(19) United States
(12) Patent Application Publication
(10) Pub. No.: US 2026/0197937 A1
(43) Pub. Date: Jul. 9, 2026

(54) STRETCHABLE RIGID-FLEX INTERCONNECTION STRUCTURE WITH GRADIENT STIFFNESS

(71) Applicants: MFLEX (YAN CHENG) CO., LTD., YANCHENG (CN); AGENCY FOR SCIENCE, TECHNOLOGY AND RESEARCH, SINGAPORE (SG); DSBJ PTE. LTD., SINGAPORE (SG)

(72) Inventors: YEOW MENG TAN, SINGAPORE (SG); ZHISAN HAN, SINGAPORE (SG); QIAN RU CHAN, SINGAPORE (SG)

(73) Assignees: MFLEX (YAN CHENG) CO., LTD., YANCHENG (CN); AGENCY FOR SCIENCE, TECHNOLOGY AND RESEARCH, SINGAPORE (SG); DSBJ PTE. LTD., SINGAPORE (SG)

(21) Appl. No.: 19/363,663

(22) Filed: Oct. 21, 2025

Related U.S. Application Data
(63) Continuation of application No. PCT/CN2025/071384, filed on Jan. 9, 2025.

(51) Int. Cl. H05K 1/02; H05K 1/09

(52) U.S. Cl. CPC H05K 1/0283; H05K 1/092

(57) ABSTRACT

This application discloses a stretchable rigid-flex interconnection structure with gradient stiffness, including a support body, a stretchable substrate, a stretchable circuit layer, a non-stretchable circuit layer, and a sealing layer, where the non-stretchable circuit layer is electrically connected to the stretchable circuit layer and there is an overlapping region at an interface therebetween, and a projection of the support body onto the stretchable substrate covers a projection of the non-stretchable circuit layer onto the stretchable substrate; the stretchable circuit layer has a stretching direction and a normal direction, and the support body has gradient stiffness along the stretching direction or along the normal direction. The stretchable rigid-flex interconnection structure of this application, based on the support body with the gradient stiffness, can reduce a risk of disconnection and fracture that are prone to occurring at an interconnection interface.

### CROSS-REFERENCE OF RELATED APPLICATION

This application claims priority to Singapore Patent Application No. SG10202400291S, filed on Jan. 31, 2024, which is incorporated herein by reference in its entirety, and claims priority to China Patent Application No. 2024109707967, entitled “STRETCHABLE RIGID-FLEX INTERCONNECTION STRUCTURE WITH GRADIENT STIFFNESS”, filed on Jul. 19, 2024, with DAS of B4FC, which is incorporated herein by reference in its entirety.

### TECHNICAL FIELD

This application relates to the field of rigid-flex interconnection technologies, and specifically, to a rigid-flex interconnection structure with gradient stiffness.

### BACKGROUND

With the development of science and technology, rigid-flex interconnectors have been widely used in medical, military, robotics, and other fields, especially in the field of wearable electronic technologies. The rigid-flex interconnect is an electronic system that has both a rigid circuit system (referring to a rigid and non-stretchable circuit system) and a flexible circuit system (referring to a flexible and stretchable circuit system), and an electrical interconnection is needed between the two circuit systems.

At present, most rigid-flex interconnectors use a manner of designing serpentine circuits within flexible circuit systems or manufacturing circuits directly using stretchable silver paste to reduce tensile stress of the interconnectors, so that the rigid-flex interconnectors have the ability to be stretchable. However, in the foregoing rigid-flex interconnectors, little attention is paid to designs of the rigid circuit system and the flexible circuit system at an interconnection interface, and cumulative strain damage of wearable electronic apparatuses having the rigid-flex interconnectors caused by cyclic stretching usually occurs at the interconnection interface between the rigid circuit system and the flexible circuit system. In other words, after cyclic stretching (for example, 250 cycles of stretching), the interconnection interface may be prone to disconnection and fracture, thereby causing poor stability and reliability of a rigid-flex interconnected electronic product such as a wearable electronic apparatus.

### SUMMARY

In view of this, this application provides a stretchable rigid-flex interconnection structure with gradient stiffness, to solve a problem that an existing rigid-flex interconnection structure is prone to disconnection and fracture at an interconnection interface after a plurality of stretching cycles, thereby causing poor stability and reliability of a product.

This application provides a stretchable rigid-flex interconnection structure with gradient stiffness, including:
a support body;
a stretchable substrate, disposed on one side of the support body;
a stretchable circuit layer and a non-stretchable circuit layer, both disposed on a side that is of the stretchable substrate and that is away from the support body, where the non-stretchable circuit layer is disposed opposite to the support body, the non-stretchable circuit layer is electrically connected to the stretchable circuit layer, the non-stretchable circuit layer and the stretchable circuit layer have an overlapping region at an interface, and a projection of the support body onto the stretchable substrate covers a projection of the non-stretchable circuit layer onto the stretchable substrate; and
a sealing layer, disposed on a side that is of the stretchable circuit layer and that is away from the stretchable substrate, and covering the stretchable circuit layer, where
the stretchable circuit layer has a stretching direction and a normal direction, and the support body has gradient stiffness along the stretching direction of the stretchable circuit layer, or the support body has gradient stiffness along the normal direction of the stretchable circuit layer.

Optionally, when the support body has the gradient stiffness along the normal direction of the stretchable circuit layer, the support body includes:
a first material layer and at least two second material layers, where an elastic modulus of the first material layer is greater than or equal to that of the second material layer, and a projection of the first material layer onto the stretchable substrate covers the projection of the non-stretchable circuit layer onto the stretchable substrate; and
all the second material layers are sequentially stacked on a side that is of the stretchable substrate and that is away from the non-stretchable circuit layer according to a first specified order, and the first material layer is stacked on an outer side of one second material layer that is farthest away from the non-stretchable circuit layer.

Optionally, in the support body, according to the first specified order, second spacings between all the second material layers and the stretchable circuit layer along the stretching direction sequentially increase, and a first spacing between the first material layer and the stretchable circuit layer along the stretching direction is greater than a second spacing between one second material layer that is farthest away from the non-stretchable circuit layer and the stretchable circuit layer, so that all outer edges that are of the second material layers and that are close to the stretchable circuit layer form a stepped stacked structure together with an outer edge that is of the first material layer and that is close to the stretchable circuit layer.

Optionally, the elastic moduli of all the second material layers are the same, or the elastic moduli of all the second material layers sequentially increase according to the first specified order.

Optionally, when the support body has the gradient stiffness along the stretching direction of the stretchable circuit layer, the support body includes:
a first material layer and a second material layer, where an elastic modulus of the first material layer is greater than or equal to that of the second material layer, and a projection of the first material layer onto the stretchable substrate covers the projection of the non-stretchable circuit layer onto the stretchable substrate; and
the second material layer is disposed on a side that is of the stretchable substrate and that is away from the non-stretchable circuit layer, and the first material layer is embedded in the second material layer.

Optionally, both the first material layer and the second material layer have thicknesses greater than 0.1 mm.

Optionally, the elastic moduli of both the first material layer and the second material layer are greater than or equal to an elastic modulus of the stretchable substrate.

Optionally, an elastic modulus of the second material layer is less than 0.1 GPa. Optionally, the second material layer includes any one of a silicone layer, an acrylic polymer layer, and a polyurethane layer.

Optionally, when the elastic modulus of the first material layer is greater than that of the second material layer, the first material layer includes any one of a steel layer, a reinforcing layer, an FR-4 base layer, a polycarbonate layer, a polyethylene terephthalate layer, and a polyimide layer.

Optionally, when the support body has the gradient stiffness along the stretching direction of the stretchable circuit layer, the support body includes:
at least two third material layers sequentially laid on a side that is of the stretchable substrate and that is away from the non-stretchable circuit layer according to a second specified order, where all the third material layers are coplanar and edge lines of two adjacent third material layers at an interface overlap; and
according to the second specified order, the elastic moduli of all the third material layer sequentially increase, and a projection of a third material layer with a largest elastic modulus onto the stretchable substrate covers the projection of the non-stretchable circuit layer onto the stretchable substrate.

Optionally, all the third material layers have thicknesses greater than 0.1 mm.

Optionally, the elastic moduli of all the third material layers are greater than or equal to an elastic modulus of the stretchable substrate.

Optionally, the elastic modulus of the third material layer with the largest elastic modulus among all the third material layers is greater than 0.1 GPa, and the elastic moduli of the remaining third material layers are all less than 0.1 GPa.

Optionally, the third material layer with the largest elastic modulus among all the third material layers includes any one of a steel layer, a reinforcing layer, an FR-4 base layer, a polycarbonate layer, a polyethylene terephthalate layer, and a polyimide layer, the remaining third material layers include any one of a silicone layer, an acrylic polymer layer, and a polyurethane layer.

Optionally, the stretchable substrate includes:
a polymer film layer and a hot melt adhesive layer that are sequentially stacked, both the stretchable circuit layer and the non-stretchable circuit layer are attached to an outer side of the polymer film layer, and the support body is attached to an outer side of the hot melt adhesive layer; and
the polymer film layer has a thickness of 75 μm, and/or the hot melt adhesive layer has a thickness of 25 μm.

Optionally, the polymer film layer includes any one of a silicone film layer, an acrylic polymer film layer, and a polyurethane film layer.

Optionally, the stretchable circuit layer is made of a liquid metal polymer composite, where
the liquid metal polymer composite is specifically a mixture of silver powder, liquid metal and styrene-ethylene-butylene-styrene block copolymer, and weight percentages of the silver powder, the liquid metal, and the styrene-ethylene-butylene-styrene block copolymer in the liquid metal polymer composite are 28.2%, 68.3%, and 3.4% respectively.

Optionally, a length of the overlapping region between the non-stretchable circuit layer and the stretchable circuit layer along the stretching direction of the stretchable circuit layer is greater than or equal to 0.1 mm.

Optionally, the non-stretchable circuit layer is made of silver paste.

This application has the beneficial effects as follows: The stretchable substrate is disposed on one side of the support body. The stretchable circuit layer and the non-stretchable circuit layer are separately disposed on the side that is of the stretchable substrate and that is away from the support body. The two circuit layers form the flexible circuit system and the rigid circuit system respectively, which are electrically connected to each other, have an overlapping region at an interface, and constitute a stretchable interconnection structure. The non-stretchable circuit layer is disposed opposite to the support body, and the projection of the support body onto the stretchable substrate covers the projection of the non-stretchable circuit layer onto the stretchable substrate, so that the support body can be better utilized to provide good support for the non-stretchable circuit layer, and the rigid circuit system can be effectively prevented from being damaged when the rigid-flex interconnection structure is stretched. The gradient stiffness means that the stiffness of the material is not unique and constant, but changes in a gradient manner. Therefore, the support body has the gradient stiffness along the stretching direction or has the gradient stiffness along the normal direction of the stretchable circuit layer, so that when the rigid-flex interconnection structure is stretched, a degree of stress concentration at the interconnection interface can be lowered, stress transferred from the stretchable substrate to the non-stretchable circuit layer can be further relieved, stress received by the rigid circuit system can be reduced, thereby reducing the risk of disconnection and fracture between the rigid circuit system and the flexible circuit system at the interconnection interface after a plurality of stretching cycles, and effectively ensuring the stability and reliability of an electronic product using the rigid-flex interconnection structure. The sealing layer is disposed on the side that is of the stretchable circuit layer and that is sway from the stretchable substrate, which can play a role in sealing and protecting the stretchable circuit layer, further improving the stability and reliability of the product.

The stretchable rigid-flex interconnection structure with gradient stiffness of this application, based on the support body with the gradient stiffness, can reduce the risk of disconnection and fracture at the interconnection interface in the rigid-flex interconnection structure after a plurality of stretching cycles, and has high stability and reliability.

### BRIEF DESCRIPTION OF THE DRAWINGS

Features and advantages of this application will be more clearly understood with reference to the accompanying drawings, which are schematic and should not be construed as limiting this application in any way. In the accompanying drawings:

FIG. 1 is a top view of a structure of a stretchable rigid-flex interconnection structure with gradient stiffness according to an embodiment of this application;

FIG. 2 is a partial cross-sectional view of a structure of a stretchable rigid-flex interconnection structure with gradient stiffness according to an embodiment of this application;

FIG. 3 is a cross-sectional view of a structure of a first alternative embodiment of a support body in this application;

FIG. 4 is a cross-sectional view of a structure of a second alternative embodiment of a support body in this application;

FIG. 5 is a cross-sectional view of a structure of a third alternative embodiment of a support body in this application;

FIG. 6 is a cross-sectional view of a structure of a stretchable substrate according to an embodiment of this application;

FIG. 7 is a top view of a structure of another stretchable rigid-flex interconnection structure with gradient stiffness according to an embodiment of this application;

FIG. 8 is a stretchability test curve of an embodiment sample in a first group of comparative experiments according to an embodiment of this application;

FIG. 9A is a physical image of the embodiment sample in the first group of comparative experiments according to the embodiment of this application;

FIG. 9B is an enlarged view of an interconnection interface corresponding to the embodiment sample in the first group of comparative experiments according to the embodiment of this application;

FIG. 10 is a physical image of comparative sample 1 in the first group of comparative experiments according to the embodiment of this application;

FIG. 11A and FIG. 11B are enlarged views of two interconnection interfaces of comparative sample 1 in the first group of comparative experiments according to the embodiment of this application;

FIG. 12 is a stretchability test statistics graph of an embodiment sample and comparative sample 2 in a second group of comparative experiments according to an embodiment of this application;

FIG. 13A is a stress distribution diagram of comparative sample 2 on an upper surface of a stretchable substrate in the second group of comparative experiments according to the embodiment of this application;

FIG. 13B is a stress distribution diagram of the embodiment sample on the upper surface of the stretchable substrate in the second group of comparative experiments according to the embodiment of this application;

FIG. 14A is a stress distribution diagram of comparative sample 2 on a lower surface of the stretchable substrate in the second group of comparative experiments according to the embodiment of this application; and

FIG. 14B is a stress distribution diagram of the embodiment sample on the lower surface of the stretchable substrate in the second group of comparative experiments according to the embodiment of this application.

### REFERENCE NUMERALS

1: support body; 2: stretchable substrate; 3: stretchable circuit layer; 4: non-stretchable circuit layer; 5: overlapping region; 6: sealing layer; 7: electronic component; 8: interconnection interface; 11: first material layer; 12: second material layer; 13: third material layer; 21: polymer film layer; 22: hot melt adhesive layer.

### DETAILED DESCRIPTION OF PREFERRED EMBODIMENTS

To make objectives, technical solutions, and advantages of embodiments of this application clearer, the following clearly and completely describes the technical solutions in the embodiments of this application with reference to the accompanying drawings in the embodiments of this application. It is clear that the described embodiments are merely some rather than all of embodiments of this application. All other embodiments obtained by a person skilled in the art based on embodiments of this application without creative efforts shall fall within the protection scope of this application.

In the descriptions of this application, it should be understood that orientations or positional relationships indicated by the terms “upper”, “lower”, and the like are orientations or positional relationships as shown in the drawings, and are only for the purpose of facilitating and simplifying the descriptions of this application instead of indicating or implying that apparatuses or elements indicated must have particular orientations, and be constructed and operated in the particular orientations, so that these terms are not construed as limiting this application.

It should be noted that, in this application, relational terms such as “first” and “second” are merely used to distinguish one entity or operation from another entity or operation, and do not necessarily require or imply any actual relationship or order between these entities or operations. Moreover, the terms “include,” “comprise,” or any other variant thereof are intended to cover non-exclusive inclusions, such that a process, method, article, or device including a series of elements includes not only those elements, but also other elements that are not explicitly listed, or may further include elements inherent to such a process, method, article, or device. Without further limitation, an element defined by the phrase “comprising/including a . . . ” does not preclude the existence of other identical elements in a process, method, article, or device including the element.

### Embodiment

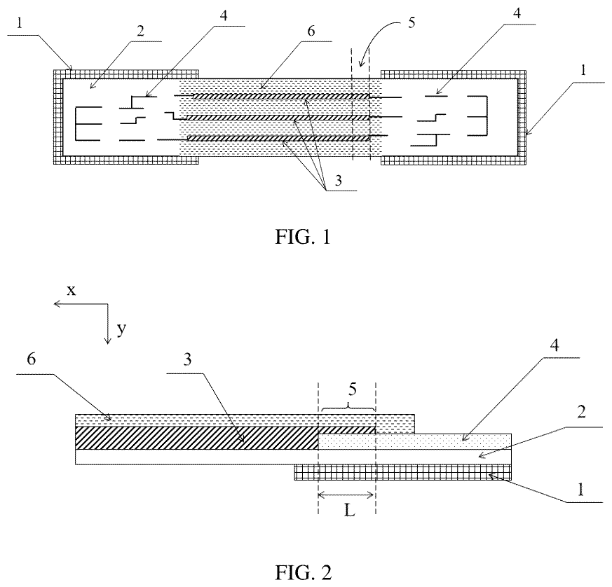

This embodiment provides a stretchable rigid-flex interconnection structure with gradient stiffness. As shown in FIG. 1 and FIG. 2, FIG. 1 is a top view of a structure of the interconnection structure, and FIG. 2 is a cross-sectional view of a structure of an interconnection interface therein. The interconnection structure includes:
a support body 1;
a stretchable substrate 2, disposed on one side of the support body 1;
a stretchable circuit layer 3 and a non-stretchable circuit layer 4, both disposed on a side that is of the stretchable substrate 2 and that is away from the support body 1, where the non-stretchable circuit layer 4 is disposed opposite to the support body 1, the non-stretchable circuit layer 4 is electrically connected to the stretchable circuit layer 3, the non-stretchable circuit layer 4 and the stretchable circuit layer 3 have an overlapping region 5 at an interface, and a projection of the support body 1 onto the stretchable substrate 2 covers a projection of the non-stretchable circuit layer 4 onto the stretchable substrate 2; and
a sealing layer 6, disposed on a side that is of the stretchable circuit layer 3 and that is away from the stretchable substrate 2, and covering the stretchable circuit layer 3, where
the stretchable circuit layer 3 has a stretching direction and a normal direction, and the support body 1 has gradient stiffness along the stretching direction of the stretchable circuit layer 3, or the support body 1 has gradient stiffness along the normal direction of the stretchable circuit layer 3.

In this embodiment, the stretchable substrate is disposed on one side of the support body. The stretchable circuit layer and the non-stretchable circuit layer are separately disposed on the side that is of the stretchable substrate and that is away from the support body. The two circuit layers form the flexible circuit system and the rigid circuit system respectively, which are electrically connected to each other, have an overlapping region at the interface, and constitute a stretchable interconnection structure. The non-stretchable circuit layer is disposed opposite to the support body, and the projection of the support body onto the stretchable substrate covers the projection of the non-stretchable circuit layer onto the stretchable substrate, so that the support body can be better utilized to provide good support for the non-stretchable circuit layer, and the rigid circuit system can be effectively prevented from being damaged when the rigid-flex interconnection structure is stretched. The gradient stiffness means that material stiffness is not unique and constant, but changes in a gradient manner. Therefore, the support body has the gradient stiffness along the stretching direction or has the gradient stiffness along the normal direction of the stretchable circuit layer, so that when the rigid-flex interconnection structure is stretched, a degree of stress concentration at the interconnection interface can be lowered, stress transferred from the stretchable substrate to the non-stretchable circuit layer can be further relieved, stress received by the rigid circuit system can be reduced, thereby reducing the risk of disconnection and fracture between the rigid circuit system and the flexible circuit system at the interconnection interface after a plurality of stretching cycles, and effectively ensuring the stability and reliability of an electronic product using the rigid-flex interconnection structure. The sealing layer is disposed on the side that is of the stretchable circuit layer and that is sway from the stretchable substrate, which can play a role in sealing and protecting the stretchable circuit layer, further improving the stability and reliability of the product.

The stretchable rigid-flex interconnection structure with gradient stiffness of this embodiment, based on the support body with the gradient stiffness, can reduce the risk of disconnection and fracture at the interconnection interface in the rigid-flex interconnection structure after a plurality of stretching cycles, and has high stability and reliability.

In this embodiment, material stiffness is the ability of a material to resist elastic deformation when stressed. It is a mechanical property of a material, indicating the ease with which the shape and size of the material change when stressed. The greater the stiffness, the smaller the deformation of the material when subjected to the same acting force. The stiffness can be expressed by the elastic modulus. The elastic modulus describes the proportional relationship between stress and strain of the material under unidirectional stress. Therefore, the stiffness is jointly determined by the elastic modulus and a structure size. When the structure size is fastened, the greater the elastic modulus, the greater the stiffness.

Each assembly part of the stretchable rigid-flex interconnection structure with gradient stiffness in this embodiment is described in detail below.

In FIG. 2, the stretching direction of the stretchable circuit layer 3 is specifically the x direction in FIG. 2, and the normal direction includes an upward normal direction and a downward normal direction. In this embodiment, the normal direction means the downward normal direction, that is, the y direction in FIG. 2.

The support body 1 has gradient stiffness in the x direction or has gradient stiffness in the y direction, so that a degree of stress concentration at the interconnection interface can be lowered, the stress transferred from the stretchable substrate to the non-stretchable circuit layer can be relieved, and the stresses received in the rigid circuit system can be reduced, thereby reducing the risk of disconnection and fracture at the interconnection interface. Certainly, in a finer design, the support body 1 may alternatively have gradient stiffness in the x direction and gradient stiffness in the y direction at the same time.

Preferably, when the support body has the gradient stiffness along the normal direction (that is, the y direction) of the stretchable circuit layer, the support body 1 includes:
a first material layer 11 and at least two second material layers 12, where an elastic modulus of the first material layer 11 is greater than or equal to that of the second material layer 12, and a projection of the first material layer 11 onto the stretchable substrate 2 covers the projection of the non-stretchable circuit layer 4 onto the stretchable substrate 2; and
all the second material layers 12 are sequentially stacked on a side that is of the stretchable substrate and that is away from the non-stretchable circuit layer 4 according to a first specified order, and the first material layer 11 is stacked on an outer side of one second material layer 12 that is farthest away from the non-stretchable circuit layer 4.

There are two or more second material layers, so that a fine support body structure can be obtained, the stress distribution can then be more evenly, and the stress transferred from the stretchable substrate to the non-stretchable circuit layer can be gradually relieved, which effectively reduces the risk of disconnection and fracture of the interconnection interface on the basis of ensuring that the rigid-flex interconnection structure has excellent stretchability. The elastic modulus of the first material layer is greater than or equal to that of the second material layer, and the projection of the first material layer onto the stretchable substrate covers the projection of the non-stretchable circuit layer onto the stretchable substrate, which can ensure that a material layer with a largest elastic modulus in the support body plays a role in supporting the non-stretchable circuit layer, thereby ensuring that the support body effectively plays a role in supporting the non-stretchable circuit layer, and effectively preventing the rigid circuit system from being damaged when the rigid-flex interconnection structure is stretched.

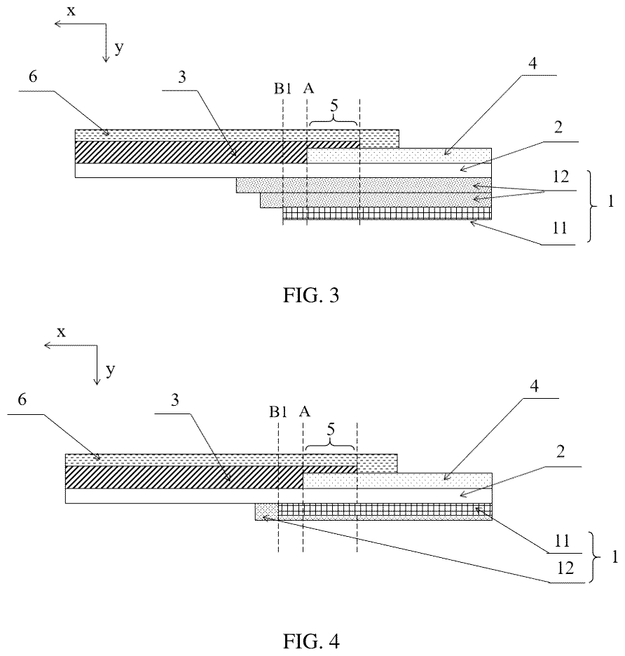

The foregoing structure is a first alternative embodiment of the support body. As shown in FIG. 3, there are two second material layers 12. The two second material layers 12 are sequentially stacked on a side that is of the stretchable substrate 2 and that is away from the non-stretchable circuit layer 4 according to a first specified order, and the first material layer 11 is stacked on an outer side of one second material layer 12 that is farthest away from the non-stretchable circuit layer 4, that is, stacked on the outermost second material layer 12. The second material layer 12 on the outermost layer is specifically the bottommost second material layer 12 in FIG. 3.

In the foregoing first alternative embodiment, the plurality of second material layers are sequentially stacked on the side that is of the stretchable substrate and that is away from the stretchable circuit layer, and the first material layer is stacked on the second material layer at the outermost layer. The first material layer and the second material layer are stacked in a multi-level manner. Gradient stiffness in the normal direction may be implemented based on thickness superposition of the first material layer and the plurality of second material layers, so that the entire support body has gradient stiffness in the normal direction, thereby effectively reducing the risk of disconnection and fracture at the interconnection interface.

It should be understood that FIG. 3 only shows two second material layers, and cases having other numbers of second material layers are similar, and are not listed herein.

Preferably, in the support body 1 of the foregoing first alternative embodiment, according to the first specified order, second spacings between all the second material layers 12 and the stretchable circuit layer 3 along the stretching direction sequentially increase, and a first spacing between the first material layer 11 and the stretchable circuit layer 3 along the stretching direction is greater than a second spacing between one second material layer 12 that is farthest away from the non-stretchable circuit layer 4 and the stretchable circuit layer 3, so that all outer edges that are of the second material layers 12 and that are close to the stretchable circuit layer 3 form a stepped stacked structure together with an outer edge that is of the first material layer 11 and that is close to the stretchable circuit layer 3.

The first spacing between the first material layer and the stretchable circuit layer along the stretching direction means a center spacing between the first material layer and the stretchable circuit layer along the x direction. Similarly, the second spacing between the second material layer and the stretchable circuit layer along the stretching direction means a center spacing between the second material layer and the stretchable circuit layer along the x direction. In the foregoing first alternative embodiment, the second spacings sequentially increase, and the first spacing is greater than the second spacing, which is equivalent to that the second material layer is closer to the stretchable circuit layer in the x direction than all the first material layers. Due to the stepped stacked structure formed by the outer edges that are of the two material layers and that are close to the stretchable circuit layer, the stiffness may gradually decrease along the stretching direction, and may gradually increase toward the non-stretchable circuit layer, that is, gradient stiffness is formed along the stretching direction, so that the function of a strain buffer may be achieved at the interconnection interface, and the stress transferred from the stretchable substrate to the non-stretchable circuit layer is hierarchically relieved.

Preferably, in the foregoing first alternative embodiment, the elastic moduli of all the second material layers 12 are the same, or the elastic moduli of all the second material layers 12 sequentially increase according to the first specified order.

For the second material layers that are sequentially stacked, elastic moduli of the layers may be the same, or may sequentially increase along the first specified order (that is, a stacking order, specifically means the y direction in FIG. 3), which both can ensure that a support body with gradient stiffness along the y direction is obtained.

Preferably, when the support body 1 has the gradient stiffness along the stretching direction of the stretchable circuit layer 3, as shown in FIG. 4, the support body 1 includes:
a first material layer 11 and a second material layers 12, where an elastic modulus of the first material layer 11 is greater than or equal to that of the second material layer 12, and a projection of the first material layer 11 onto the stretchable substrate 2 covers the projection of the non-stretchable circuit layer 4 onto the stretchable substrate 2; and
the second material layer 12 is disposed on a side that is of the stretchable substrate 2 and that is away from the non-stretchable circuit layer 4, and the first material layer 11 is embedded in the second material layer 12.

In the foregoing second alternative embodiment, the first material layer is embedded in the second material layer, that is, the first material layer and the second material layer are connected in an embedded manner, and gradient stiffness in the stretching direction may be implemented based on superposition of the elastic moduli of the two material layers, so that the entire support body has the gradient stiffness in the stretching direction, similarly, the function of a strain buffer may be achieved at the interconnection interface, and the risk of disconnection and fracture at the interconnection interface is effectively reduced.

For the support bodies of the foregoing two alternative embodiments, as shown in FIG. 3 and FIG. 4, the projection of the first material layer 11 onto the stretchable substrate 2 covers the projection of the non-stretchable circuit layer 4 onto the stretchable substrate 2, which means that in FIG. 3 and FIG. 4, an edge line B1 that is of the first material layer 11 and that is close to the stretchable circuit layer 3 is flush with a boundary line A between the non-stretchable circuit layer 4 and the stretchable circuit layer 3, or the line B1 exceeds the line A.

In the foregoing two alternative embodiments, both the first material layer 11 and the second material layer 12 have thicknesses greater than 0.1 mm.

The first material layer and the second material layer in the foregoing thickness range can not only play a role in supporting the non-stretchable circuit layer, but also can facilitate the formation of the support body with gradient stiffness in the normal direction, thereby ensuring that the function of stress relief is achieved.

In a specific implementation, the thickness of the first material layer 11 is 0.125 mm, and a 0.125 mm rigid PET film is used.

In the foregoing two alternative embodiments, the elastic moduli of both the first material layer 11 and the second material layer 12 are greater than or equal to an elastic modulus of the stretchable substrate 3.

That is, the elastic moduli of both the first material layer and the second material layer in the support body need to be greater than the elastic modulus of the stretchable substrate, which can ensure that stiffness of the support body is greater than that of the stretchable substrate, thereby ensuring that the non-stretchable circuit layer on the stretchable substrate is supported.

In the foregoing two alternative embodiments, an elastic modulus of the second material layer 12 is less than 0.1 GPa.

By using the elastic modulus in this range, it can be ensured that the stiffness of the support body closer to the stretchable circuit layer is smaller, and the stiffness of the support body farther away from the stretchable circuit layer is greater, thereby meeting required stretchability at the rigid-flex interconnection interface, and further ensuring that the stress transferred to the rigid circuit system is effectively relieved when the flexible circuit system is stretched.

In the foregoing two alternative embodiments, the second material layer includes any one of a silicone layer, an acrylic polymer layer, and a polyurethane layer.

The elastic modulus of the foregoing material is relatively small, and a satisfactory support body can be formed.

The silicone layer (for example, Dragon Skin silica gel produced by Smooth-On, USA) is mainly formed by cross-linking and curing of polydimethylsiloxane (PDMS) polymer, has a low Young's modulus, good flexibility and stretchability, strong corrosion resistance, and high dielectric strength, has good transparency and stability in a wide range of application temperatures, and can be used as a base material for large-area transparent flexible electronic devices or thermally stable devices. In addition, the silicone can be easily combined with electronic materials to fasten the electronic materials on a surface thereof.

The acrylic polymer layer (for example, a 3M VHB adhesive manufactured by 3M) has excellent film forming property, excellent chemical stability, good mechanical property and good processability. The polyurethane (PU for short, for example, thermoplastic polyurethanes, TPU) has a unique block molecular structure, excellent wear resistance, flexibility, tear resistance, and good elasticity, and can be adapted to various complex deformations and stretching.

In the foregoing two alternative embodiments, when the elastic modulus of the first material layer is greater than that of the second material layer, the first material layer includes any one of a steel layer, a reinforcing layer, an FR-4 base layer, a polycarbonate layer, a polyethylene terephthalate layer, and a polyimide layer.

When the elastic modulus of the first material layer is greater than the elastic modulus of the second material layer, the first material layer uses the foregoing material, which can ensure that the support body exhibits relatively high stiffness in a region where the second material layer is located, thereby obtaining a support body with gradient stiffness that is satisfactory.

The steel layer is made of steel. The reinforcing layer is made of an organic glass fiber reinforcing material. The organic glass fiber reinforcing material includes glass fiber and epoxy resin. The FR-4 base layer is made of glass fiber reinforced epoxy resin. The polycarbonate layer is made of PC, that is, polycarbonate, which is a thermoplastic plastic. The polyethylene terephthalate layer is made of PET, that is, polyethylene terephthalate, which is a thermoplastic polyester. The polyimide layer is made of PI, that is, polyimide.

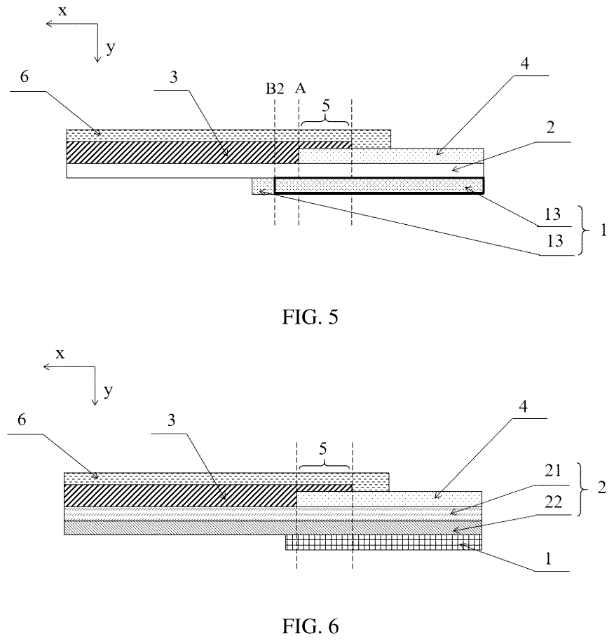

Preferably, as shown in FIG. 5, when the support body 1 has the gradient stiffness along the stretching direction of the stretchable circuit layer, the support body 1 includes:
at least two third material layers 13 sequentially laid on a side that is of the stretchable substrate 2 and that is away from the stretchable circuit layer 3 according to a second specified order, where all the third material layers 13 are coplanar and edge lines of two adjacent third material layers at an interface overlap; and
according to the second specified order, the elastic moduli of all the third material layer 13 sequentially increase, and a projection of the third material layer 13 with the largest elastic modulus onto the stretchable substrate 2 covers the projection of the non-stretchable circuit layer 4 onto the stretchable substrate 2.

The foregoing structure is a third alternative embodiment of the support body. All third material layers are coplanar and edge lines of two adjacent third material layers at an interface overlap, that is, a support body in a continuous and flat form can be obtained. The elastic moduli of these third material layers sequentially increase according to the second specified order (specifically, the direction toward the non-stretchable circuit layer, that is, the direction opposite to the x direction in the figure), so that the stiffness of the entire support body sequentially decreases along the stretching direction, and sequentially increases toward the non-stretchable circuit layer. Based on the elastic moduli of these materials, gradient stiffness in the stretching direction is implemented, thereby effectively reducing the risk of disconnection and fracture at the interconnection interface.

For the support body of the foregoing third alternative embodiment, as shown in FIG. 5, the projection of the third material layer 13 with the largest elastic modulus onto the stretchable substrate 2 covers the projection of the non-stretchable circuit layer 4 onto the stretchable substrate 2, which means that an edge line B2 that is of the rightmost third material layer 13 and that is close to the stretchable circuit layer 3 in FIG. 5 is flush with a boundary line A between the non-stretchable circuit layer 4 and the stretchable circuit layer 3, or the line B2 exceeds the line A.

It should be understood that FIG. 5 only shows a case having two third material layers, and cases having other numbers of third material layers are similar, and are not presented herein.

In the foregoing third alternative embodiment, all the third material layer 13 have thicknesses greater than 0.1 mm.

Similar to the foregoing two alternative embodiments, the third material layer in the foregoing thickness range can not only play a role in supporting the non-stretchable circuit layer, but also can facilitate the formation of a support body with gradient stiffness in a normal direction, thereby ensuring that the function of stress relief is achieved.

In a specific implementation, the thickness of the third material layer 13 with the largest elastic modulus among all the third material layers 13 is specifically 0.125 mm, and a 0.125 mm rigid PET film is used.

In the foregoing third alternative embodiment, the elastic moduli of all the third material layers 13 are greater than or equal to an elastic modulus of the stretchable substrate 2.

The elastic moduli of all the third material layers in the support body need to be greater than the elastic modulus of the stretchable substrate, which can ensure that stiffness of the support body is greater than that of the stretchable substrate, thereby ensuring that the non-stretchable circuit layer on the stretchable substrate is supported.

In the foregoing third alternative embodiment, the elastic modulus of the third material layer 13 with the largest elastic modulus among all the third material layers 13 is greater than 0.1 GPa, and the elastic moduli of the remaining third material layers 13 are all less than 0.1 GPa.

By using the third material layer with the foregoing elastic modulus, it can be ensured that the stiffness of the support body closer to the stretchable circuit layer is smaller, and the stiffness of the support body farther away from the stretchable circuit layer is greater, thereby meeting required stretchability at the rigid-flex interconnection interface, and further ensuring that the stress transferred to the rigid circuit system is effectively relieved when the flexible circuit system is stretched.

In the foregoing third alternative embodiment, the third material layer 13 with the largest elastic modulus among all the third material layers 13 includes any one of a steel layer, a reinforcing layer, an FR-4 base layer, a polycarbonate layer, a polyethylene terephthalate layer, and a polyimide layer, the remaining third material layers 13 include any one of a silicone layer, an acrylic polymer layer, and a polyurethane layer.

By using the third material layer of the foregoing material, it can also be ensured that the stiffness of the support body closer to the stretchable circuit layer is smaller, and the stiffness of the support body farther away from the stretchable circuit layer is greater, thereby meeting required stretchability at the rigid-flex interconnection interface, and further ensuring that the stress transferred to the rigid circuit system is effectively relieved when the flexible circuit system is stretched.

Preferably, as shown in FIG. 6, the stretchable substrate 2 includes:
a polymer film layer 21 and a hot melt adhesive layer 22 that are sequentially stacked, where both the stretchable circuit layer 3 and the non-stretchable circuit layer 4 are attached to an outer side of the polymer film layer 21, and the support body 1 is attached to an outer side of the hot melt adhesive layer 22.

The polymer film layer has a better elongation, and the entire stretchable substrate can have good stretchability by using the polymer film layer, which is convenient for providing excellent stretchability for the flexible circuit system together with the stretchable circuit layer. The hot melt adhesive layer can provide good adhesion, which is convenient for easy attachment of the support layer, and ensures that good support is provided for the non-stretchable circuit layer, thereby forming the rigid circuit system with excellent quality.

It should be understood that when the polymer film layer 21 and the hot melt adhesive layer 22 are sequentially stacked, the outer side of the polymer film layer 21 and the outer side of the hot melt adhesive layer 22 are two outer surfaces of the entire stretchable substrate 2 (that is, upper and lower surfaces of the stretchable substrate 2 in FIG. 6).

Preferably, the polymer film layer 21 includes any one of a silicone film layer, an acrylic polymer film layer, and a polyurethane film layer.

The foregoing polymer film layers can all ensure that the stretchable substrate has good stretchability.

In a specific implementation, a TPU5855 film is used for the stretchable substrate 2, that is, the polymer film layer 21 is a TPU film with a thickness of 75 μm, exhibiting higher elongation, such as typical elongation at fracture of more than 500%, and good recovery ability, such as less than 5% permanent deformation after 100% strain. The hot melt adhesive layer 22 is an FDS5855X1 hot melt adhesive with a thickness of 25 μm.

Preferably, the stretchable circuit layer 3 is made of a liquid metal polymer composite.

The liquid metal polymer composite is specifically a mixture of silver powder, liquid metal, and styrene-ethylene-butylene-styrene block copolymer.

Liquid metal is a good electrical conductor for flexible and stretchable media. However, it is difficult to directly use the liquid metal as conductive ink because the liquid metal may quickly form an oxide layer that hinders wetting of the substrate. In this embodiment, a liquid metal polymer composite (LMPC for short) is used, which not only maintains material characteristics of the liquid metal, that is, it is flexible and stretchable, but also can overcome disadvantages of the liquid metal and can avoid rapid formation of an oxide layer that hinders the wetting of the substrate. In this embodiment, both flaky silver powder and a compatible stretchable polymer (that is, styrene-ethylene-butylene-styrene block copolymer) binder are added, and the liquid metal is used as a dual phase in an Ag/bonder matrix, which can improve processability of the liquid metal.

Specifically, weight percentages of the silver powder, the liquid metal, and the styrene-ethylene-butylene-styrene block copolymer in the liquid metal polymer composite are 28.2%, 68.3%, and 3.4% respectively.

The stretchable circuit layer formed by the liquid metal polymer composite (LMPC) with the foregoing weight percentages has excellent stretchability and can be used in regions requiring high tensile strain in rigid-flex interconnectors. The stretchable circuit layer can be used not only as a conductive wire in a flexible circuit system, but also as a strain relief device of a rigid-flex interconnector. In addition, when the separated flaky Ag powder is stretched apart, the liquid metal in the LMPC acts as a “healing” medium to bridge the separation, so as to maintain electrical continuity.

Specifically, the liquid metal is specifically a gallium-indium alloy, and a weight ratio of gallium to indium in the gallium-indium alloy is 3:1.

When the weight ratio of gallium to indium in the gallium-indium alloy is 3:1, the alloy has the advantages of low melting point, good thermal stability, high electrical conductivity, good plasticity and ductility, and the like, and can facilitate the manufacturing of the liquid metal polymer composite and ensure functionality of the formed stretchable circuit layer.

In a specific implementation, the stretchable circuit layer 3 has a thickness ranging from 1μ m to 300μ m.

Preferably, as shown in FIG. 2, a length of the overlapping region 5 between the non-stretchable circuit layer 4 and the stretchable circuit layer 3 along the stretching direction of the stretchable circuit layer 3 is greater than or equal to 0.1 mm.

By limiting the length of the overlapping region, an electronic interconnection at an interconnection interface between the flexible circuit system and the rigid circuit system can be better ensured, thereby effectively ensuring functionality of the rigid-flex interconnector. In addition, it is further convenient for the sealing layer to better fill edges of the stretchable circuit layer, to better encapsulate or seal the stretchable circuit layer, and to play a better sealing role.

In FIG. 2, the stretching direction of the stretchable circuit layer 3 is the x direction in the figure, so that a length of the overlapping region 5 at the interface of the non-stretchable circuit layer 4 and the stretchable circuit layer 3 along the x direction is more than or equal to 0.1 mm.

Preferably, the non-stretchable circuit layer 4 is made of silver paste.

The silver paste is electrically conductive, can be flexible but not stretchable after preparation, and has good chemical stability and is not prone to oxidization. Even if a surface of the silver paste is partially oxidized, obtained oxide may also be conductive. The silver paste has good adhesion to the substrate and is not easy to fall off the stretchable substrate, so that a rigid circuit system with excellent quality and no stretchability can be formed.

In a specific implementation, the silver paste in the non-stretchable circuit layer 4 may be ASH LS-411 or ASH LS-453 type silver paste, which can maintain good conductivity when strain is kept within 10%.

In a specific implementation, the non-stretchable circuit layer 4 has a thickness ranging from 1 μm to 100 μm.

Preferably, the sealing layer 6 includes a film layer including any one or a combination of several of a silicone layer, an acrylic polymer layer, and a polyurethane layer.

The foregoing sealing layer can not only encapsulate or seal the stretchable circuit layer, but also ensure that the sealing layer further has stretchability, to be conveniently stretched together with the stretchable circuit layer, so as to implement the rigid-flex interconnection structure with excellent stretchability.

In a specific implementation, the sealing layer 6 uses an ecoflex-010 silicone layer with a thickness of 0.25 mm.

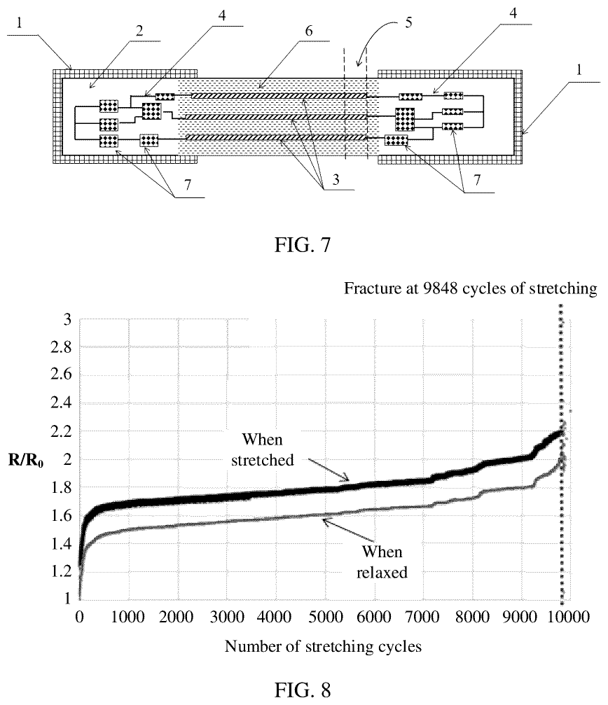

Preferably, as shown in FIG. 7, further included are:
a plurality of electronic components 7, mounted to a side that is of the non-stretchable circuit layer 4 and that is away from the stretchable substrate 2, where each electronic component 7 is electrically connected to the non-stretchable circuit layer 4.

Through the mounted electronic components and electrical connections between the electronic components and the non-stretchable circuit layer, a final rigid circuit system can be formed according to actual product design requirements, thereby obtaining a rigid-flex interconnection structure with high stability and reliability.

The electronic component in this embodiment is an electronic component such as a resistor, a capacitor, or a diode, and a specific type thereof depend on a specific product design.

To present advantages of the stretchable rigid-flex interconnection structure with gradient stiffness in this embodiment, the following two groups of comparative experiments are further performed in this embodiment.

First group: Comparative sample 1 is compared with a sample of the stretchable rigid-flex interconnection structure with gradient stiffness in this embodiment (for ease of description, referred to as an embodiment sample), where comparative sample 1 only includes a circuit layer and a stretchable substrate, which means that stretchable silver paste (such as commercial stretchable ink LS-453) is used as the circuit layer, and the circuit layer is directly applied to the stretchable substrate described in this embodiment.

Second group: Comparative sample 2 is compared with the sample of the stretchable rigid-flex interconnection structure with gradient stiffness in this embodiment (for ease of description, referred to as an embodiment sample), where comparative sample 2 and the sample of the stretchable rigid-flex interconnection structure with gradient stiffness in this embodiment only differ in the support body part, and structures and materials of other parts are the same. The support body of comparative sample 2 is a rigid PET film with no gradient stiffness.

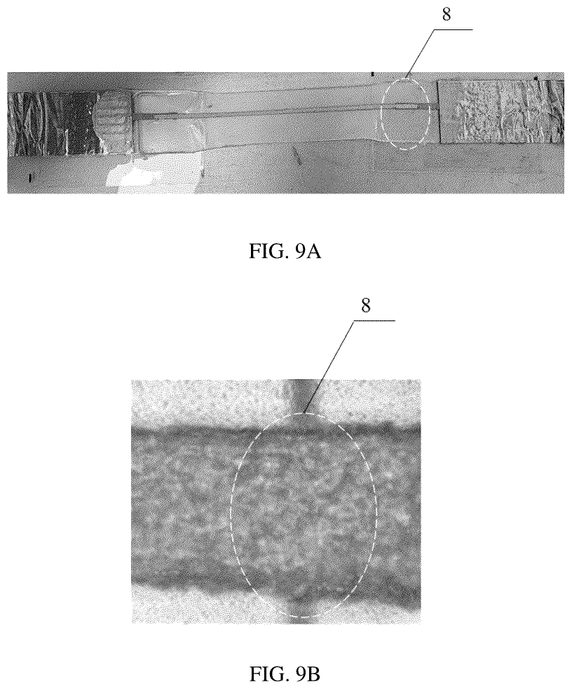

For the first group of comparative experiments, two samples (that is, comparative sample 1 and the embodiment sample) in a first group of samples are separately subjected to tensile tests, where the tensile test of the embodiment sample is performed at 100% strain and a stretching rate of 3 mm/sec, and tensile test of comparative sample 1 is performed at 50% strain and at a stretching rate of 0.6 mm/sec and 6 mm/sec, respectively. A stretchability test curve of an embodiment sample is shown in FIG. 8. In FIG. 8, a resistance ratio of the embodiment sample after about 10,000 cycles of stretching (that is, R/R₀, a ratio of a resistance of the stretchable conductive trace after cyclic stretching to an initial resistance before stretching) is stable, and is approximately 2.20 at 9823 cycles of stretching (where R₀ ranges from 1Ω to 2Ω, which is suitable for most electronic applications). In addition, the interconnection interface between the rigid circuit system and the flexible circuit system shows no signs of fracturing at 2000 cycles of stretching, as shown in FIG. 9A and FIG. 9B. FIG. 9A is a physical image of the embodiment sample at the 2000 cycles of stretching. FIG. 9B is an enlarged view of the corresponding interconnection interface of the embodiment sample at the 2000 cycles of stretching. In FIG. 9A and FIG. 9B, dotted boxes indicate the interconnection interface 8.

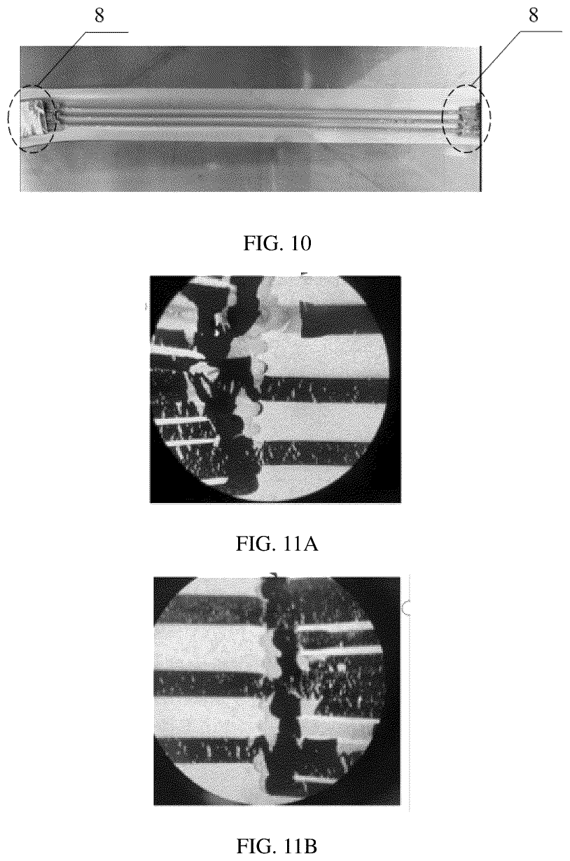

Stretchability test results of the comparative sample 1 are shown in Table 1. It can be learned from Table 1 that the comparative sample 1 exhibits a very large R/R₀ and fractures at the interconnection interface, as shown in FIG. 10, FIG. 10 is a physical image of comparative sample 1, and a dashed box also indicates the interconnection interface 8. FIG. 11A and FIG. 11B are enlarged views of the two interconnection interfaces 8 of the comparative sample 1. This shows that the stretchable rigid-flex interconnection structure with gradient stiffness in this embodiment enhances stretchability and bonding performance, which can be widely applied in stretchable electronic apparatuses.

TABLE 1
Stretchability test results of comparative sample 1
Stretchability test (250 cycles of stretching; 50% strain)

| | Stretching | | R/R₀ (when | R/R₀ (when |
|---|---|---|---|---|
| Number | speed (mm/s) | R₀ (Ω) | stretched) | relaxed) |
| 1 | 0.6 | 2.43 | 33.4 | 8.5 |
| 2 | 0.6 | 3.26 | 68.8 | 8.8 |

| | | | |
|---|---|---|---|
| 3 | 6.0 | 3.25 | The circuit is not conductive at 49 |
| | | | cycles of stretching |

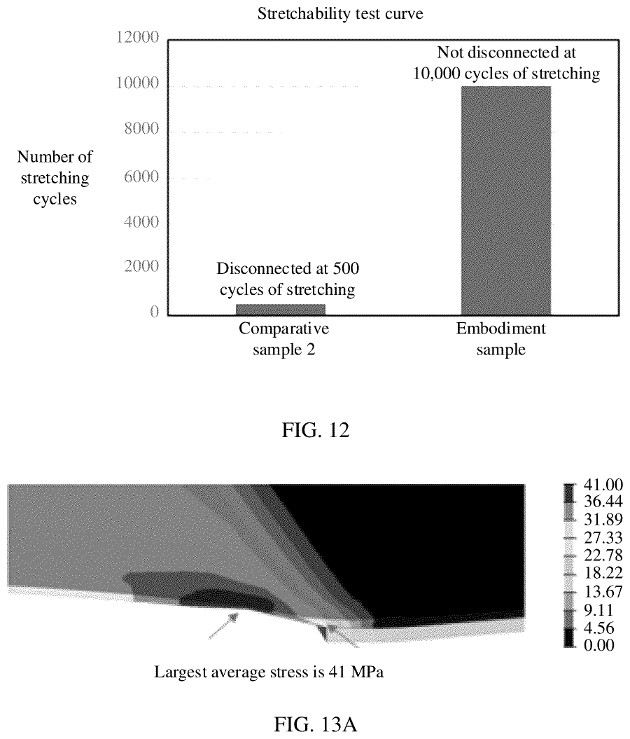

For the second group of comparative experiments, two samples (that is, comparative sample 2 and the embodiment sample) in a second group of samples are separately subjected to stretchability tests, the stretchability tests of the two samples are both conducted at 100% strain and a stretching rate of 3 mm/sec. A statistical graph of the tensile test is shown in FIG. 12. It can be learned from FIG. 12 that comparative sample 2 is disconnected at 500 cycles of stretching, and the embodiment sample is not disconnected at 10,000 cycles of stretching. Comparative data of the stretchability tests are shown in Table 2. It can be learned from Table 2 that the circuit is disconnected and the resistance became infinite when comparative sample 2 has been subjected to less than 1,000 cycles of stretching, and the electronic circuit is not disconnected when the embodiment sample has been subjected to more than 10,000 cycles of stretching.

TABLE 2
Comparative data table of stretchability tests
of comparative sample 2 and embodiment sample

| | |
|---|---|
| Comparative | The electronic circuit is disconnected after less than 1,000 |
| sample 2 | cycles and the resistance becomes infinite. |
| Embodiment | The electronic circuit is not disconnected after more than |
| sample | 10,000 cycles, and is still conductive |

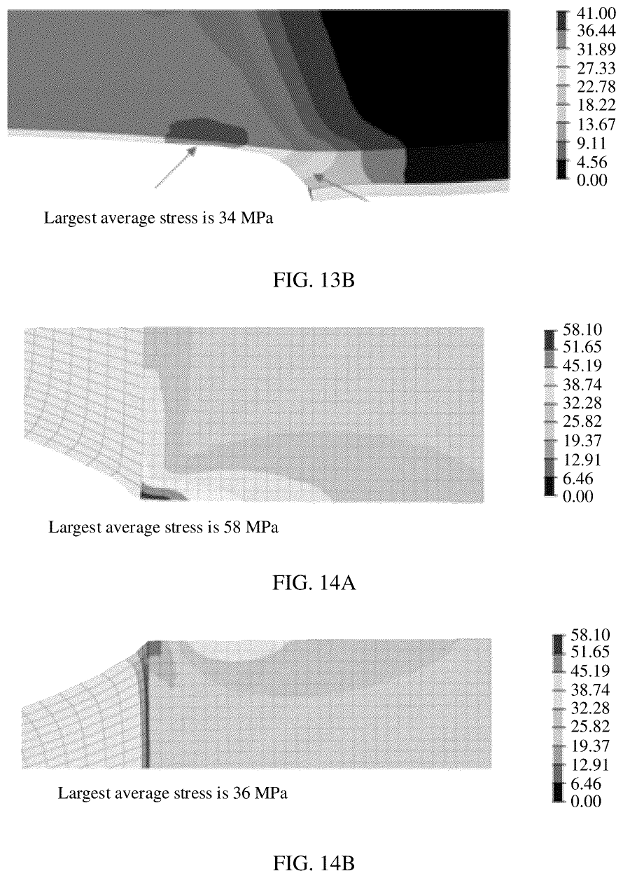

For the second group of comparative experiments, stress distribution simulations are further performed on two samples in the second group of samples. The stress distribution simulations include simulation of stress distribution on the upper surface of the stretchable substrate (that is, an interface where the stretchable substrate meets the stretchable circuit layer and the non-stretchable circuit layer) and simulation of stress distribution on the lower surface of the stretchable substrate (that is, an interface between the stretchable substrate and the support body). A stress distribution diagram of comparative sample 2 on the upper surface of the stretchable substrate is shown in FIG. 13A, and a largest average stress is 41 MPa. A stress distribution diagram of the embodiment sample on the upper surface of the stretchable substrate is shown in FIG. 13B, and a largest average stress is 34 MPa. A stress distribution diagram of comparative sample 2 on the lower surface of the stretchable substrate is shown in FIG. 14A, and a largest average stress is 58 MPa. A stress distribution diagram of the embodiment sample on the lower surface of the stretchable substrate is shown in FIG. 14B, and a largest average stress is 36 MPa.

Therefore, the stretchable rigid-flex interconnection structure with gradient stiffness in this embodiment has not only better stretchability but also an effective reduction in the largest average stress, less risk of disconnection and fracture and higher stability and reliability.

Although embodiments of this application have been described with reference to the accompanying drawings, various modifications and variations may be made by those skilled in the art without departing from the spirit and scope of this application, and such modifications and variations fall within the scope defined by the appended claims.

1. A stretchable rigid-flex interconnection structure with gradient stiffness, comprising:
a support body;
a stretchable substrate, disposed on one side of the support body;
a stretchable circuit layer and a non-stretchable circuit layer, both disposed on a side that is of the stretchable substrate and that is away from the support body, wherein the non-stretchable circuit layer is disposed opposite to the support body, the non-stretchable circuit layer is electrically connected to the stretchable circuit layer, the non-stretchable circuit layer and the stretchable circuit layer have an overlapping region at an interface, and a projection of the support body onto the stretchable substrate covers a projection of the non-stretchable circuit layer onto the stretchable substrate; and
a sealing layer, disposed on a side that is of the stretchable circuit layer and that is away from the stretchable substrate, and covering the stretchable circuit layer, wherein
the stretchable circuit layer has a stretching direction and a normal direction, and the support body has gradient stiffness along the stretching direction of the stretchable circuit layer, or the support body has gradient stiffness along the normal direction of the stretchable circuit layer.

2. The stretchable rigid-flex interconnection structure with gradient stiffness according to claim 1, wherein when the support body has the gradient stiffness along the normal direction of the stretchable circuit layer, the support body comprises:
a first material layer and at least two second material layers, wherein an elastic modulus of the first material layer is greater than or equal to that of the second material layer, and a projection of the first material layer onto the stretchable substrate covers the projection of the non-stretchable circuit layer onto the stretchable substrate; and
all the second material layers are sequentially stacked on a side that is of the stretchable substrate and that is away from the non-stretchable circuit layer according to a first specified order, and the first material layer is stacked on an outer side of one second material layer that is farthest away from the non-stretchable circuit layer.

3. The stretchable rigid-flex interconnection structure with gradient stiffness according to claim 2, wherein in the support body, according to the first specified order, second spacings between all the second material layers and the stretchable circuit layer along the stretching direction sequentially increase, and a first spacing between the first material layer and the stretchable circuit layer along the stretching direction is greater than a second spacing between one second material layer that is farthest away from the non-stretchable circuit layer and the stretchable circuit layer, so that all outer edges that are of the second material layers and that are close to the stretchable circuit layer form a stepped stacked structure together with an outer edge that is of the first material layer and that is close to the stretchable circuit layer.

4. The stretchable rigid-flex interconnection structure with gradient stiffness according to claim 2, wherein the elastic moduli of all the second material layers are the same, or the elastic moduli of all the second material layers sequentially increase according to the first specified order.

5. The stretchable rigid-flex interconnection structure with gradient stiffness according to claim 1, wherein when the support body has the gradient stiffness along the stretching direction of the stretchable circuit layer, the support body comprises:
a first material layer and a second material layer, wherein an elastic modulus of the first material layer is greater than or equal to that of the second material layer, and a projection of the first material layer onto the stretchable substrate covers the projection of the non-stretchable circuit layer onto the stretchable substrate; and
the second material layer is disposed on a side that is of the stretchable substrate and that is away from the non-stretchable circuit layer, and the first material layer is embedded in the second material layer.

6. The stretchable rigid-flex interconnection structure with gradient stiffness according to claim 2, wherein both the first material layer and the second material layer have thicknesses greater than 0.1 mm.

7. The stretchable rigid-flex interconnection structure with gradient stiffness according to claim 2, wherein the elastic moduli of both the first material layer and the second material layer are greater than or equal to an elastic modulus of the stretchable substrate.

8. The stretchable rigid-flex interconnection structure with gradient stiffness according to claim 7, wherein the elastic modulus of the second material layer is less than 0.1 GPa.

9. The stretchable rigid-flex interconnection structure with gradient stiffness according to claim 2, wherein the second material layer comprises any one of a silicone layer, an acrylic polymer layer, and a polyurethane layer.

10. The stretchable rigid-flex interconnection structure with gradient stiffness according to claim 2, wherein when the elastic modulus of the first material layer is greater than that of the second material layer, the first material layer comprises any one of a steel layer, a reinforcing layer, an FR-4 base layer, a polycarbonate layer, a polyethylene terephthalate layer, and a polyimide layer.

11. The stretchable rigid-flex interconnection structure with gradient stiffness according to claim 1, wherein when the support body has the gradient stiffness along the stretching direction of the stretchable circuit layer, the support body comprises:
at least two third material layers sequentially laid on a side that is of the stretchable substrate and that is away from the non-stretchable circuit layer according to a second specified order, wherein all the third material layers are coplanar and edge lines of two adjacent third material layers at an interface overlap; and
according to the second specified order, the elastic moduli of all the third material layer sequentially increase, and a projection of a third material layer with a largest elastic modulus onto the stretchable substrate covers the projection of the non-stretchable circuit layer onto the stretchable substrate.

12. The stretchable rigid-flex interconnection structure with gradient stiffness according to claim 11, wherein all the third material layers have thicknesses greater than 0.1 mm.

13. The stretchable rigid-flex interconnection structure with gradient stiffness according to claim 11, wherein the elastic moduli of all the third material layers are greater than or equal to an elastic modulus of the stretchable substrate.

14. The stretchable rigid-flex interconnection structure with gradient stiffness according to claim 11, wherein the elastic modulus of the third material layer with the largest elastic modulus among all the third material layers is greater than 0.1 GPa, and the elastic moduli of the remaining third material layers are all less than 0.1 GPa.

15. The stretchable rigid-flex interconnection structure with gradient stiffness according to claim 11, wherein the third material layer with the largest elastic modulus among all the third material layers comprises any one of a steel layer, a reinforcing layer, an FR-4 base layer, a polycarbonate layer, a polyethylene terephthalate layer, and a polyimide layer, and the remaining third material layers comprise any one of a silicone layer, an acrylic polymer layer, and a polyurethane layer.

16. The stretchable rigid-flex interconnection structure with gradient stiffness according to claim 1, wherein the stretchable substrate comprises:
a polymer film layer and a hot melt adhesive layer that are sequentially stacked, both the stretchable circuit layer and the non-stretchable circuit layer are attached to an outer side of the polymer film layer, and the support body is attached to an outer side of the hot melt adhesive layer; and
the polymer film layer has a thickness of 75 μm, and/or the hot melt adhesive layer has a thickness of 25 μm.

17. The stretchable rigid-flex interconnection structure with gradient stiffness according to claim 16, wherein the polymer film layer comprises any one of a silicone film layer, an acrylic polymer film layer, and a polyurethane film layer.

18. The stretchable rigid-flex interconnection structure with gradient stiffness according to claim 1, wherein the stretchable circuit layer is made of a liquid metal polymer composite; and
the liquid metal polymer composite is specifically a mixture of silver powder, liquid metal, and styrene-ethylene-butylene-styrene block copolymer, and weight percentages of the silver powder, the liquid metal, and the styrene-ethylene-butylene-styrene block copolymer in the liquid metal polymer composite are 28.2%, 68.3%, and 3.4% respectively.

19. The stretchable rigid-flex interconnection structure with gradient stiffness according to claim 1, wherein a length of the overlapping region between the non-stretchable circuit layer and the stretchable circuit layer along the stretching direction of the stretchable circuit layer is greater than or equal to 0.1 mm.

20. The stretchable rigid-flex interconnection structure with gradient stiffness according to claim 1, wherein the non-stretchable circuit layer is made of silver paste.
